(19) United States
(12) Patent Application Publication
(10) Pub. No.: US 2026/0297382 A1
(43) Pub. Date: Oct. 1, 2026

(54) POLISHING COMPOSITION

(71) Applicant: FUJIMI INCORPORATED, Aichi (JP)

(72) Inventors: Sonosuke ISHIGURO, Aichi (JP); Shintaro MAKI, Aichi (JP); Yuki OZEKI, Aichi (JP); Shota SUZUKI, Aichi (JP)

(21) Appl. No.: 19/558,856

(22) Filed: Mar. 6, 2026

(30) Foreign Application Priority Data
Mar. 28, 2025 (JP) 2025-056938

(51) Int. Cl. C09G 1/02; C09K 3/14; H10P 52/40

(52) U.S. Cl. CPC C09G 1/02; C09K 3/1436; H10P 52/407

(57) ABSTRACT

An object of the present invention is to provide a novel polishing composition enabling a carbon film to be polished at a high polishing removal rate.

A polishing composition containing a cation-modified abrasive having an average secondary particle diameter of 80 nm or more, a water-soluble polymer having a highest occupied molecular orbital (HOMO) energy level of −10.00 eV or more, and a liquid carrier.

### TECHNICAL FIELD

The present invention relates to a polishing composition.

### BACKGROUND ART

In recent years, higher integration and higher performance of semiconductor integrated circuits (Large-Scale Integration, hereinafter, referred to as “LSI”.) have progressed. In particular, DRAM (Dynamic Random Access Memory) and 3D-NAND have made dramatic progress in storage capacity through miniaturization or multi-layering. With advancement in miniaturization or multi-layering, it has become necessary to form contact holes with higher aspect ratios.

Formation of contact holes can be achieved by lithography and dry etching. In the case of forming patterns with particularly high aspect ratios, hard masks are used. Hard masks are films with high etching resistance to dry etching. As hard masks, silicon nitride films have been conventionally used, and carbon films with higher etching resistance have also been utilized.

Amorphous carbon films, nanocrystalline diamond films, graphene films, and the like have been proposed as carbon films used in hard masks. These films can be formed by chemical vapor deposition methods (Chemical Vapor Deposition, hereinafter, also referred to as “CVD”), physical vapor deposition methods (Physical Vapor Deposition, hereinafter, also referred to as “PVD”), spin-coating methods, or the like.

Carbon films more easily suffer from increased surface roughness during film formation, as compared with silicon nitride films which have been conventionally used. If surfaces of carbon films are rough, failures may occur in lithography processes or dry etching processes to cause malfunctions of elements. Therefore, if carbon films can be polished and thus surfaces of such carbon films can be smoothened, it is expected that malfunctions of elements can be reduced and productivity can be enhanced. Thus, in order to smoothen surfaces of carbon films, there is a need for sufficient removal of at least surface layer portions of carbon films, and thus there is a demand for high-speed polishing of carbon films.

For example, Patent Literature 1 discloses, as a carbon film polishing technique, a polishing liquid containing an abrasive, a tetravalent cerium ion, and water.

The technique described in the Patent Literature 1 had the problem of low polishing removal rate of a carbon film. Then, Patent Literature 2 proposes, for polishing a carbon film at a high polishing removal rate, a polishing composition containing an abrasive, a pH adjusting agent, and water, in which the average secondary particle diameter of the abrasive is more than 120 nm, the abrasive includes cation-modified silica, and the pHis 7 or less.

### CITATION LIST

### Patent Literature

[Patent Literature 1] International Publication No. WO 2021/084706
[Patent Literature 2] Japanese Patent Laid-Open No. 2023-42685

### SUMMARY DISCLOSURE

### Technical Problem

An object of the present invention is to provide a novel polishing composition enabling a carbon film to be polished at a high polishing removal rate.

### Solution to Problem

There is provided a polishing composition containing a cation-modified abrasive having an average secondary particle diameter of 80 nm or more, a water-soluble polymer having a highest occupied molecular orbital (HOMO) energy level of −10.00 eV or more, and a liquid carrier.

### Effect of the Disclosure

According to the present invention, there is provided a solution enabling a carbon film to be polished at a high polishing removal rate.

### DESCRIPTION OF EMBODIMENTS

Herein, “X to Y” is used to mean that numerical values (X and Y) described before and after “to” are included as the lower limit value and the upper limit value, and means “X or more and Y or less”. In a case where a plurality of descriptions “X to Y” is made, for example, in a case where “X1 to Y1, or, X2 to Y2”, “X1 or more and Y1 or less, or, X2 or more and Y2 or less” is described, all of the disclosure where each numerical value is adopted as the upper limit, the disclosure where each numerical value is adopted as the lower limit, and the disclosure of any combination of such upper limit and lower limit are made (namely, these disclosures serve as legitimate bases for amendments). Specifically, all of the amendment to X1 or more, the amendment to Y2 or less, the amendment to X1 or less, the amendment to Y2 or more, the amendment to X1 to X2, the amendment to X1 to Y2, and the like need to be regarded as legitimate. Herein, the description “X or more” means X or more than X and thus encompasses the meaning “more than X”. Similarly, the description “Y or less” means Y or less than Y and thus encompasses the meaning “less than Y”. Unless particularly noted, operations, and measurement of physical properties and the like are made under conditions of room temperature (20 to 25° C.) and a relative humidity of 40 to 50% RH. The concentration described herein may be a concentration at POU (Point-of-use) or a concentration before dilution to the concentration at POU. The dilution factor may be 2 to 10-fold. It is to be understood that all combinations of embodiments and descriptions disclosed herein are disclosed in the present application. In other words, it is to be understood that these combinations can serve as legitimate bases for amendments. In a case where the content or the concentration of each component is described and two or more kinds of such components are included, the total amount of such components can be adopted.

The polishing composition disclosed in the present invention is a polishing composition containing a cation-modified abrasive having an average secondary particle diameter of 80 nm or more, a water-soluble polymer having a highest occupied molecular orbital (HOMO) energy level of −10.00 eV or more, and a liquid carrier. According to such a configuration, a carbon film can be polished at a high polishing removal rate.

### [Object to be Polished]

The object to be polished in the present invention preferably includes a carbon film. Here, the “carbon film” is not limited to a film composed of a carbon simple substance, and also encompasses a carbon film containing other atom(s) (hydrogen atom, oxygen atom, and/or the like) than a carbon atom. Examples of the carbon film include an amorphous carbon film (hereinafter, also referred to as “amorphous carbon film”), a diamond-like carbon film (Diamond Like Carbon, hereinafter, also referred to as “DLC”), a nanocrystalline diamond film, a graphene film, a SiC film, and a SiOC film. The types of these films may be adopted singly or in combinations of two or more kinds thereof. Among these, an amorphous carbon film, a diamond-like carbon film, a nanocrystalline diamond film, and a graphene film are preferred. These films can be formed by CVD, PVD, a spin-coating method, or the like.

The content of the carbon atom in the carbon film is sequentially preferably 10% by mass or more, 30% by mass or more, 50% by mass or more, 60% by mass or more, 70% by mass or more, 80% by mass or more, 90% by mass or more, 92% by mass or more, 95% by mass or more, 97% by mass or more, 98% by mass or more, or 99% by mass or more based on the total mass of the carbon film. The carbon film may also be in a form substantially composed of carbon (the content of the carbon atom is substantially 100% by mass).

The object to be polished in the present invention may further include any other material than the carbon film. Examples of such any other material include silicon nitride, silicon oxide, single-crystalline silicon, multi-crystalline silicon (polysilicon), non-crystalline silicon (amorphous silicon), n-type or p-type impurity-doped multi-crystalline silicon, n-type or p-type impurity-doped non-crystalline silicon, titanium nitride, a metal simple substance, and SiGe.

Examples of the object to be polished including silicon oxide include a TEOS (Tetraethyl Orthosilicate) type silicon oxide surface (hereinafter, also referred to as “TEOS” or “TEOS film”) produced with tetraethyl orthosilicate as a precursor, a HDP (High Density Plasma) film, an USG (Undoped Silicate Glass) film, a PSG (Phosphorus Silicate Glass) film, a BPSG (Boron-Phospho Silicate Glass) film, and a RTO (Rapid Thermal Oxidation) film.

According to one embodiment of the present invention, the object to be polished does not include silicon oxide.

Examples of the metal simple substance include tungsten, copper, cobalt, hafnium, nickel, gold, silver, platinum, palladium, rhodium, ruthenium, iridium, and osmium.

### [Abrasive]

The polishing composition according to the present invention contains a cation-modified abrasive as an abrasive. The cation-modified abrasive may be used singly or in combinations of two or more kinds thereof.

The cation-modified abrasive is preferably cation-modified silica (silica having a cationic group), or is preferably cation-modified colloidal silica (colloidal silica having a cationic group). Here, the “cation-modified” means a state where a cationic group (for example, an amino group or a quaternary ammonium group) is chemically bound to surfaces of at least some particles constituting the abrasive. According to a preferred embodiment of the present invention, the cation-modified abrasive is amino group-modified silica particles, more preferably an amino group-modified colloidal silica particles. According to such an embodiment, the above effects can be more enhanced.

The cation-modified abrasive used here may be a commercially available product or a synthetic product, and is preferably one obtained by a method including cation-modifying a raw material (in particular, a silica raw material) with a silane coupling agent. Hereinafter, there is described with, as an example, the method for producing the cation-modified silica.

### [Method for Producing Cation-Modified Abrasive]

### [Silica Raw Material]

The silica raw material is a raw material before cation modification (property modification) with a predetermined silane coupling agent described later, and includes a silica particle. The silica raw material is preferably colloidal silica. Hereinafter, the colloidal silica as the silica raw material is also referred to as “raw material colloidal silica”, and is described in detail with, as an example, a case where the silica raw material is raw material colloidal silica.

The raw material colloidal silica can be, for example, one produced by a sol-gel method. The raw material colloidal silica produced by a sol-gel method is preferred because the content of a corrodible ion having dispersibility in a semiconductor, such as a metal impurity or chloride ion, is low. Production of the raw material colloidal silica by a sol-gel method can be performed with a conventionally known procedure, and specifically the raw material colloidal silica can be obtained by hydrolysis-condensation reaction in which a hydrolyzable silicon compound (for example, alkoxysilane or its derivative) is used as a raw material. This silicon compound may be used singly or in combinations of two or more kinds thereof. The raw material colloidal silica may also be one produced by a method other than a sol-gel method.

In one embodiment, the silicon compound is preferably an alkoxysilane represented by the following general formula (1), or a derivative thereof.

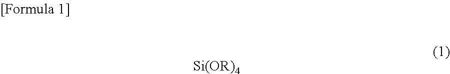

In the general formula (1), R is an alkyl group, and is preferably a lower alkyl group having 1 or more and 8 or less carbon atoms, more preferably a lower alkyl group having 1 or more and 4 or less carbon atoms. Here, R is, for example, a methyl group, an ethyl group, a propyl group, an isopropyl group, a butyl group, a pentyl group, or a hexyl group, and preferred is tetramethoxysilane where R is a methyl group, or tetraethoxysilane where R is an ethyl group, or tetraisopropoxysilane where R is an isopropyl group. Examples of the derivative of the alkoxysilane include a low concentrate obtained by partial hydrolysis of the alkoxysilane.

The silicon compound is hydrolytically condensed in a reaction solvent and thus formed into colloidal silica. Water or an organic solvent containing water can be used as the reaction solvent. Examples of the organic solvent include hydrophilic organic solvents, for example, alcohols such as methanol, ethanol, isopropanol, n-butanol, t-butanol, pentanol, ethylene glycol, propylene glycol and 1,4-butanediol, and ketones such as acetone and methyl ethyl ketone. Among these organic solvents, in particular, alcohols such as methanol, ethanol, and isopropanol are preferably used, and an alcohol having the same alkyl group as the alkyl group (R) of the silicon compound as a raw material (for example, methanol with respect to tetramethoxysilane) is preferably used from the viewpoint of post-treatment of the reaction solvent. These organic solvents may be used singly or in combinations of two or more kinds thereof. The amount of the organic solvent used is not particularly limited, and is preferably about 5 mol or more and 50 mol or less per mol of the silicon compound. When the amount is 5 mol or more, sufficient compatibility with the silicon compound is ensured, and when the amount is 50 mol or less, a reduction in production efficiency is suppressed. The amount of water added in the organic solvent is not particularly limited and may be an amount necessary for hydrolysis of the silicon compound, and the amount is preferably about 2 mol or more and 15 mol or less per mol of the silicon compound. The amount of water to be mixed in the organic solvent has a large effect on the particle diameter of colloidal silica to be formed. An increase in the amount of addition of water can increase the particle diameter of the colloidal silica. A decrease in the amount of addition of water can decrease the particle diameter of the colloidal silica. Accordingly, the mixing ratio of water and the organic solvent can be changed to arbitrarily adjust the particle diameter of colloidal silica to be produced.

It is preferable to add a basic catalyst to a reaction solvent of hydrolytic condensation reaction of the silicon compound for obtaining colloidal silica and thus adjust the reaction solvent to alkalinity (Stober method). Thus, the reaction solvent is preferably adjusted so as to have a pH of 8 or more and 11 or less, more preferably a pH of 8.5 or more and 10.5 or less, and colloidal silica can be rapidly formed. The basic catalyst is preferably an organic amine or ammonia from the viewpoint of preventing incorporation of impurities, and in particular, examples of preferred one include ethylenediamine, diethylenetriamine, triethylenetetraamine, ammonia, urea, ethanolamine, and tetramethylammonium hydroxide.

In order to hydrolytically condense the silicon compound in the reaction solvent, the silicon compound as a raw material may be added to the organic solvent and stirred in a temperature condition of 0° C. or more and 100° C. or less, preferably 0° C. or more and 50° C. or less. The silicon compound can be hydrolytically condensed in the organic solvent containing water, thereby obtaining colloidal silica uniform in particle diameter. A commercially available product, if present, may be used as the colloidal silica raw material.

The silica particle included in the silica raw material is usually present in the form of a secondary particle as an aggregate of primary particles. The average particle diameter of the secondary particle of the silica particle (average secondary particle diameter) is not particularly limited, and can be 80 nm or more and 500 nm or less, 90 nm or more and 490 nm or less, 100 nm or more and 480 nm or less, 110 nm or more and 470 nm or less, 120 nm or more and 460 nm or less, more than 120 nm and 500 nm or less, 130 nm or more and 450 nm or less, 150 nm or more and 400 nm or less, 175 nm or more and 350 nm or less, 190 nm or more and 300 nm or less, or 200 nm or more and 250 nm or less. As the value of the average secondary particle diameter, a value is adopted which is measured as the volume average particle diameter by a dynamic light scattering method with a particle diameter distribution measurement apparatus (UPA-UT151, manufactured by Nikkiso Co., Ltd.), as described in the section of Examples described later.

The lower limit of the average primary particle diameter of the silica particle included in the silica raw material can be 50 nm or more, 60 nm or more, or 70 nm or more. The upper limit of the average primary particle diameter of the silica particle can be 300 nm or less, 250 nm or less, 200 nm or less, 150 nm or less, or 100 nm or less. The average primary particle diameter of the silica raw material can be calculated with the formula SA=4TR2 under the assumption that the shape of the silica particle is a full sphere, based on the specific surface area (SA) of the silica particle, as calculated from a BET method.

The concentration of the silica particle in the silica raw material may be adjusted depending on the intended use of the silica, is not particularly limited, and is preferably 5% by mass or more, more preferably 10% by mass or more and 60% by mass or less, further preferably 15% by mass or more and 50% by mass or less from the viewpoint of productivity. In this regard, the balance obtained by removing the silica content, in the silica raw material, is water or the like serving as a liquid carrier, or a trace of a catalyst or the like. In consideration of the range of the concentration of the silica particle described above, the concentration of the liquid carrier in the silica raw material is preferably 95% by mass or less, more preferably 40% by mass or more and 90% by mass or less, further preferably 50% by mass or more and 90% by mass or less. The content of the organic solvent in the liquid carrier is more preferably lower as described above. From this viewpoint, the proportion of water content under the assumption that the total amount of the liquid carrier is 100% by mass is preferably 90% by mass or more, more preferably 95% by mass or more, further preferably 98% by mass or more, particularly preferably 100% by mass. In a case where the liquid carrier contains an organic solvent, examples of such an organic solvent include organic solvents described above, such as methanol, ethanol, and isopropanol. In particular, it is preferable to use an alcohol whose type is the same as that of the alcohol produced by hydrolysis of the silicon compound described above. The reason for this is because the alcohol whose type is the same as that of the alcohol produced by hydrolysis of the silicon compound can be used to facilitate recovery or recycle of the solvent.

In the production method of the present mode, one exhibiting a positive zeta potential is used as the silica raw material. A specific value of the zeta potential exhibited by the silica raw material is not particularly limited, and the value immediately before reaction with a silane coupling agent described later is preferably 10 mV or more, more preferably 20 mV or more, further preferably 30 mV or more. The lower limit value of the zeta potential is not particularly limited, and is usually about 60 mV or less. A value obtained by a method described in the section of Examples described later is adopted as the value of the zeta potential herein.

In the method for producing the cation-modified abrasive in the present mode, the pH of the silica raw material to be subjected to reaction is defined as a result of control of the zeta potential described above, and thus is usually about 5 or more and 11 or less, preferably 6 or more and 10.5 or less, more preferably 7 or more and 10 or less, although a preferred range thereof is difficult to unambiguously specify.

Various treatment steps may be, if necessary, applied to the silica raw material prepared above. Examples of such a treatment step include a step of reducing the viscosity of the silica raw material. Examples of the step of reducing the viscosity of the silica raw material include a step of adding an alkaline solution (aqueous solutions of various bases, such as ammonia water) or an organic solvent to the silica raw material. The amount of the alkaline solution or the organic solvent added here is not particularly limited, and may be appropriately set in consideration of the viscosity of the silica raw material to be obtained after addition. Thus, an advantage is that the step of reducing the viscosity of the silica raw material can be carried out to enhance the initial dispersibility of a silane coupling agent in the silica raw material and suppress aggregation of silica particles.

### [Silane Coupling Agent]

In the method for producing the cation-modified abrasive in the present mode, the above-prepared silica raw material (exhibiting a positive zeta potential) and a silane coupling agent having an amino group or a quaternary cation group are mixed. Thus, the reaction between the silica raw material (a hydroxy group present on a surface of the silica raw material) and a hydrolyzable silyl group of the silane coupling agent progresses. It is considered that, as a result, one end of the silane coupling agent is bound or adsorbs to a surface of the silica particle included in the silica raw material and other end (amino group or quaternary cation group) thereof is exposed at a large number on a surface of the silica particle.

Examples of the silane coupling agent used here include N-(β-aminoethyl)-γ-aminopropylmethyldimethoxysilane, N-(β-aminoethyl)-γ-aminopropyltrimethoxysilane, N-(β-aminoethyl)-γ-aminopropyltriethoxysilane, γ-aminopropyltriethoxysilane, γ-aminopropyltrimethoxysilane, γ-triethoxysilyl-N-(α,γ-dimethyl-butylidene) propylamine, N-phenyl-γ-aminopropyltrimethoxysilane, hydrochloride of N-(vinylbenzyl)-β-aminoethyl-γ-aminopropyltriethoxysilane, and octadecyldimethyl-(γ-trimethoxysilylpropyl)-ammonium chloride. In particular, N-(β-aminoethyl)-γ-aminopropyltrimethoxysilane, N-(β-aminoethyl)-γ-aminopropyltriethoxysilane, γ-aminopropyltriethoxysilane, or γ-aminopropyltrimethoxysilane is preferably used, and γ-aminopropyltriethoxysilane being a primary amine/ethoxy coupling agent (silane coupling agent having a primary amino group and an ethoxy group) is more preferably used because of being favorable in reactivity with the silica raw material. In the present invention, the silane coupling agent may be used singly or in combinations of two or more kinds thereof.

### [Mixing and Reaction of Silica Raw Material and Silane Coupling Agent]

In the present production method, the above-mentioned silica raw material and silane coupling agent are mixed to react the silica raw material and the silane coupling agent. Thus, a cationic group as a modification group is introduced to a surface of the silica particle, thereby obtaining the cation-modified abrasive.

When the silica raw material and a silane coupling agent having an amino group or a quaternary cation group are mixed and reacted, the silane coupling agent is preferably used without dilution or used in the state of a solution having a concentration of 5% by mass or more (water dispersion). If “addition without dilution” is regarded as addition at a concentration of “100% by mass”, the concentration of the silane coupling agent to be added is preferably 5% by mass or more, more preferably 50% by mass or more, further preferably 95% by mass or more, particularly preferably 100% by mass (addition without dilution), as described above. In a case where the silane coupling agent is added in the state of a solution to the silica raw material, the solvent constituting the solution containing the silane coupling agent is not particularly limited, and a water-free solvent is preferably used from the viewpoint of preventing the occurrence of gelation.

In the production method of the present mode, the method for mixing the silica raw material and the silane coupling agent is not particularly limited, and is preferably a method including adding the silane coupling agent to the silica raw material, from the viewpoint of suppression of gelation.

In a case where the silane coupling agent is added to the silica raw material, the mode of addition of the silane coupling agent may be collective addition, divided addition, or continuous addition, and is preferably dropping at a certain dropping rate. The dropping rate is also appropriately adjusted depending on the concentration of the silica particle, the concentration of the silane coupling agent, and the like.

The amount of addition of the silane coupling agent can be adjusted by the balance between conditions such as the specific surface area of the silica particle in the silica raw material and conditions such as the molecular weight in the silane coupling agent, and as an example, the amount based on 100% by mass of the silica particle included in the silica raw material is preferably 0.01% by mass or more, more preferably 0.03% by mass or more and 20% by mass or less, further preferably 0.05% by mass or more and 10% by mass or less, and may be, for example, 0.1% by mass or more and 5% by mass or less.

In the production method of the present mode, the mixing and reaction temperature of the silica raw material and the silane coupling agent is not particularly limited, and preferably falls within the range from ordinary temperature to the boiling point of the solvent. In the present mode, the reaction can progress even at about ordinary temperature, and thus it is preferable to allow the reaction to progress at a temperature (for example, 20° C. or more and 35° C. or less) around ordinary temperature. In other words, the production method of the present mode preferably does not include a step of heating the reaction system of the silica raw material and the silane coupling agent. An advantage is also that, even under a condition of a temperature around ordinary temperature (15° C. or more and 25° C. or less), an extremely simple operation, stirring of the reaction system for several hours, allows the substantially total amount of the silane coupling agent added to react with the silica particle in the silica raw material and causes almost no remaining of any unreacted coupling agent. Such an advantage can be utilized to allow the amount of addition of the silane coupling agent described above to be appropriately modulated in consideration of a demanded zeta potential profile of the resulting cation-modified abrasive. The stirring rate in mixing and reaction is not particularly limited.

The reaction time of the silica raw material and the silane coupling agent is not particularly limited, and is preferably 10 minutes or more and 10 hours or less, more preferably 30 minutes or more and 7 hours or less.

The reaction may be carried out with the reaction system being stirred, from the viewpoint that the reaction is allowed to efficiently progress. The stirring tool and stirring conditions used here are not particularly limited, and a conventionally known finding can be appropriately seen.

The pressure of the reaction system may be any pressure under ordinary pressure (under atmospheric pressure), under pressure, or under reduced pressure, and the reaction in the present invention can progress under ordinary pressure (under atmospheric pressure) and thus the reaction may be carried out under ordinary pressure (under atmospheric pressure).

In a case where the cation-modified abrasive obtained by the above method contains a solvent other than water, a liquid carrier mainly containing a reaction solvent may be, if necessary, replaced with water in order to increase long-term storage stability of the cation-modified abrasive. The method for replacing the solvent other than water, with water, is not particularly limited, and examples include a method including dropping water by increments under heating of the cation-modified abrasive. Examples also include a method including separating the cation-modified abrasive from the solvent other than water by precipitation/separation, centrifugation, or the like, and then re-dispersing the cation-modified abrasive in water.

The shape of the cation-modified abrasive is not particularly limited, and may be a spherical shape or a non-spherical shape. Specific examples of the non-spherical shape include various shapes, for example, polygonal columns such as a triangular column and a quadrangular column, a cylindrical shape, a bale shape in which the central portion of a cylinder is bulged as compared with an end portion, a donut shape in which the central portion of a disc penetrates, a plate shape, a so-called cocoon shape having a constriction at the central portion, a so-called associated spherical shape in which plural particles are integrated, a so-called “konpeito” shape having plural protrusions on the surface, and a rugby ball shape, but are not particularly limited thereto.

The average secondary particle diameter of the cation-modified abrasive in the present invention is 80 nm or more. The average secondary particle diameter of the cation-modified abrasive is preferably 90 nm or more, 100 nm or more, 110 nm or more, 120 nm or more, more than 120 nm, 130 nm or more, 140 nm or more, 150 nm or more, 160 nm or more, 175 nm or more, 190 nm or more, 200 nm or more, more than 200 nm, or 210 nm or more. In this regard, the upper limit of the average secondary particle diameter of the cation-modified abrasive is not particularly limited, and may be 500 nm or less, 450 nm or less, 400 nm or less, 350 nm or less, 300 nm or less, 250 nm or less, or 240 nm or less. In other words, the average secondary particle diameter of the cation-modified abrasive can be 80 nm or more and 500 nm or less, 90 nm or more and 490 nm or less, 100 nm or more and 480 nm or less, 110 nm or more and 470 nm or less, 120 nm or more and 460 nm or less, more than 120 nm and 500 nm or less, 130 nm or more and 450 nm or less, 160 nm or more and 400 nm or less, 175 nm or more and 350 nm or less, 190 nm or more and 300 nm or less, 200 nm or more and 250 nm or less, or more than 200 nm and 240 nm or less. When the average secondary particle diameter of the cation-modified abrasive falls within the above range, the polishing removal rate of the object to be polished including the carbon film can be more enhanced. The average secondary particle diameter of the cation-modified abrasive, adopted here, is a value measured by the same method as in the silica raw material, specifically a value measured by a method described in Examples.

The average primary particle diameter of the cation-modified abrasive is preferably 50 nm or more, more preferably 60 nm or more, further preferably 65 nm or more, still further preferably 70 nm or more, particularly preferably 75 nm or more. The average primary particle diameter of the cation-modified abrasive is preferably 300 nm or less, more preferably 250 nm or less, further preferably 200 nm or less, still further preferably 150 nm or less, particularly preferably 100 nm or less, most preferably 95 nm or less. In other words, the average primary particle diameter of the cation-modified abrasive is preferably 50 nm or more and 300 nm or less, more preferably 60 nm or more and 250 nm or less, further preferably 65 nm or more and 200 nm or less, still further preferably 70 nm or more and 150 nm or less, particularly preferably 75 nm or more and 100 nm or less, most preferably 80 nm or more and 95 nm or less. When the average primary particle diameter of the cation-modified abrasive falls within the above range, the polishing removal rate of the object to be polished including the carbon film can be more enhanced.

The average primary particle diameter of the cation-modified abrasive can be here calculated with the formula SA=4πR² under the assumption that the shape of the cation-modified abrasive is a full sphere, based on the specific surface area (SA) of the silica particle of the cation-modified abrasive, as calculated from a BET method, as in the average primary particle diameter of the silica raw material.

The ratio of the average secondary particle diameter to the average primary particle diameter of the cation-modified abrasive (average secondary particle diameter/average primary particle diameter, hereinafter, also referred to as “average degree of association”) is preferably more than 1.0, more preferably 1.1 or more, further preferably 1.2 or more. The average degree of association of the cation-modified abrasive is preferably 4 or less, more preferably 3.5 or less, further preferably 3 or less. In other words, the average degree of association of the cation-modified abrasive is preferably more than 1.0 and 4 or less, more preferably 1.1 or more and 3.5 or less, further preferably 2.0 or more and 3.5 or less. The average degree of association of the cation-modified abrasive is here obtained by dividing the value of the average secondary particle diameter of the cation-modified abrasive by the value of the average primary particle diameter.

The lower limit of the D90/D50 which is the ratio between the diameter (D90) at which the cumulative particle weight from the finer particle side reaches 90% of the total particle weight in a particle diameter distribution of the cation-modified abrasive, as determined by a laser diffraction scattering method, and the diameter (D50) at which the cumulative particle weight reaches 50% of the total particle weight of all particles is not particularly limited, and is preferably 1.1 or more, more preferably 1.2 or more, further preferably 1.3 or more. The upper limit of the ratio D90/D50 between the particle diameter (D90) at which the cumulative particle weight from the finer particle side reaches 90% of the total particle weight in a particle diameter distribution of the cation-modified abrasive, as determined by a laser diffraction scattering method, and the particle diameter (D50) at which the cumulative particle weight reaches 50% of the total particle weight of all particles, in the cation-modified abrasive in the polishing composition, is not particularly limited, and is preferably 2.0 or less, more preferably 1.7 or less, further preferably 1.5 or less. Such a range can allow a defect on a surface of an object to be polished to be more reduced. The D90/D50 of the cation-modified abrasive in the polishing composition (average secondary particle diameter: 210 nm, average primary particle diameter: 90 nm) in Examples was 1.498.

The sizes of the cation-modified abrasive (average primary particle diameter, average secondary particle diameter, D90/D50, and the like) can be appropriately controlled by selection of the silica raw material, selection of the method for producing the cation-modified abrasive, and the like.

The lower limit of the zeta potential of the cation-modified abrasive in the polishing composition is preferably 10 mV or more, more preferably 20 mV or more, further preferably 30 m V or more, still further preferably 40 mV or more, still further preferably 45 mV or more. The upper limit of the zeta potential of the cation-modified abrasive in the polishing composition is preferably 70 mV or less, more preferably 65 mV or less, further preferably 60 mV or less. In other words, the zeta potential of the cation-modified abrasive in the polishing composition is preferably 10 mV or more and 70 m V or less, more preferably 20 mV or more and 65 mV or less, further preferably 30 m V or more and 60 mV or less, still further preferably 40 mV or more and 58 mV or less, still further preferably 45 mV or more and 55 mV or less.

A cation-modified abrasive having the above-described zeta potential makes it possible to polish a carbon film at a higher polishing removal rate.

Herein, a value measured by the method described in Examples is adopted as the zeta potential of the cation-modified abrasive. The zeta potential of the cation-modified abrasive can be adjusted by the amount of the cationic group in the cation-modified abrasive, the pH of the polishing composition, and the like.

According to one embodiment of the present invention, the cation-modified abrasive is cation-modified colloidal silica, and the number of silanol groups in the cation-modified colloidal silica is 2/nm² or more, 2.5/nm² or more, more than 2.5/nm², 3/nm² or more, 3.5/nm² or more, more than 3.7/nm², 4/nm² or more, 4.5/nm² or more, 5/nm² or more, 5.5/nm² or more, more than 5.5/nm², 6/nm² or more, or more than 6.6/nm². According to one embodiment of the present invention, the cation-modified abrasive is cation-modified colloidal silica and the number of silanol groups in the cation-modified colloidal silica is 22/nm² or less, 20/nm² or less, 19/nm² or less, 18/nm² or less, less than 17.5/nm², 17/nm² or less, 16/nm² or less, 15/nm² or less, 14/nm² or less, 13/nm² or less, 12/nm² or less, 11/nm² or less, 10/nm² or less, 9/nm² or less, 8/nm² or less, or 7/nm² or less. According to one embodiment of the present invention, the cation-modified abrasive is cation-modified colloidal silica. When the number of silanol groups in the cation-modified colloidal silica is, in particular, more than 2.5/nm², more than 3.7/nm², more than 5.5/nm², or more than 6.6/nm², the polishing removal rate of the object to be polished including the carbon film can be more enhanced. According to one embodiment of the present invention, the number of silanol groups in the cation-modified colloidal silica is 6/nm² or more and 22/nm² or less. Such a range can allow the polishing removal rate of the object to be polished including the carbon film to be more enhanced. Examples of the method for allowing the number of silanol groups in the cation-modified colloidal silica to be 6/nm² or more and 22/nm² or less include a method including hydrothermally treating and then cation-modifying a dispersion liquid containing colloidal silica. As conditions of such hydrothermal treatment, a dispersion liquid containing the cation-modified colloidal silica is heat-treated, for example, at a temperature of 100° C. to 200° C. for 30 to 60 minutes. The method for measuring the number of silanol groups is according to the method described in Examples.

The content (concentration) of the abrasive in the polishing composition is not particularly limited, and is preferably 0.001% by mass or more, 0.005% by mass or more, 0.01% by mass or more, 0.03% by mass or more, 0.05% by mass or more, or 0.07% by mass or more. The content (concentration) of the abrasive in the polishing composition is not particularly limited, and is preferably 10% by mass or less, 5% by mass or less, 3% by mass or less, 1% by mass or less, 0.8% by mass or less, or 0.6% by mass or less based on the total mass of the polishing composition. In other words, the content (concentration) of the abrasive in the polishing composition is not particularly limited, and is preferably 0.001% by mass or more and 10% by mass or less, 0.005% by mass or more and 5% by mass or less, 0.01% by mass or more and 3% by mass or less, 0.03% by mass or more and 1% by mass or less, 0.05% by mass or more and 0.8% by mass or less, or 0.07% by mass or more and 0.6% by mass or less based on the total mass of the polishing composition.

When the content of the abrasive falls within such a range, the carbon film can be polished at a higher polishing removal rate. In a case where the polishing composition contains two or more abrasives, the content of the abrasive means the total amount of these abrasives.

The abrasive in the polishing composition according to the present invention may further include any other abrasive than the cation-modified abrasive as long as the effects of the present invention are not impaired. Such any other abrasive may be any of an inorganic particle, an organic particle, and an organic/inorganic composite particle. Specific examples of the inorganic particle include silica not cation-modified, particles made of metal oxides such as alumina, ceria, and titania, a silicon nitride particle, a silicon carbide particle, and a boron nitride particle. Specific examples of the organic particle include a polymethyl methacrylate (PMMA) particle. Such any other abrasive may be used singly or as a mixture of two or more kinds thereof. Such other abrasive used here may be a commercially available product or a synthetic product. Here, the content of such any other abrasive is preferably 20% by mass or less, more preferably 10% by mass or less, further preferably 5% by mass or less, particularly preferably 1% by mass or less based on the total mass of the abrasive. The most preferred mode is one in which no other abrasives are present (0 wt %), i.e., the abrasive consists of the cation-modified abrasive.

### [Water-Soluble Polymer]

The polishing composition according to the present invention contains a water-soluble polymer. In the water-soluble polymer, “water-soluble” means that the solubility in water (25° C.) is equal to or more than 1 g/100 mL, and “polymer” refers to a compound having a repeating unit in its molecule structure, and corresponds to a concept including a so-called oligomer. The average number of repeating units in the water-soluble polymer (for example, water-soluble polymer having a highest occupied molecular orbital (HOMO) energy level of −10.00 eV or more) can be, for example, 2 to 50. The weight average molecular weight (molecular weight) of the water-soluble polymer (for example, water-soluble polymer having a highest occupied molecular orbital (HOMO) energy level of −10.00 eV or more) can be, for example, 100 to 3000, 110 to 2000, 120 to 1500, 130 to 1000, 140 to 800, 150 to 700, 160 to 500, or 170 to 300. The weight average molecular weight (molecular weight) of the water-soluble polymer (for example, water-soluble polymer having a highest occupied molecular orbital (HOMO) energy level of −10.00 eV or more) can be, for example, more than 200, more than 400, more than 600, more than 700, or more than 800. The weight average molecular weight (molecular weight) of the water-soluble polymer (for example, water-soluble polymer having a highest occupied molecular orbital (HOMO) energy level of −10.00 eV or more) can be less than 1000, less than 800, less than 700, less than 600, or less than 400. In a case where the atomic weight of each element constituting the water-soluble polymer (for example, water-soluble polymer having a highest occupied molecular orbital (HOMO) energy level of −10.00 eV or more), and the number thereof are known, the molecular weight may be calculated based on the structure. For example, the molecular weight of 3,6-dioxa-1,8-octanediol is about 150.17.

The “weight average molecular weight” used herein can be a value of the weight average molecular weight (in terms of polyethylene glycol) measured by gel permeation chromatography (GPC). The weight average molecular weight can be measured with the following apparatus and conditions:
GPC apparatus: manufactured by Shimadzu Corporation
Model: Prominence+ELSD detector (ELSD-LTII)
Column: VP-ODS (manufactured by Shimadzu Corporation)
Mobile phase A: MeOH
   B: aqueous 1% acetic acid solution
Flow rate: 1 mL/min
Detector: ELSD temp. 40° C., Gain 8, N2GAS 350 kPa
Oven temperature: 40° C.
Amount of injection: 40 μL.

The polishing composition according to the present invention contains, as the water-soluble polymer, a water-soluble polymer having a highest occupied molecular orbital (HOMO) energy level (also referred to as HOMO level) of −10.00 eV or more. The water-soluble polymer having a highest occupied molecular orbital (HOMO) energy level of −10.00 eV or more can be contained to enhance the polishing removal rate. The inventors here considered that water-soluble polymers commonly contained in polishing compositions exert the effect of substrate protection and serve to decrease the polishing removal rates of object to be polished. For example, paragraph “0042” of International Publication No. WO 2017/163910 discloses that a water-soluble polymer (specifically, a compound containing a polyoxyalkylene chain) functions as a polishing speed inhibitor which suppresses the polishing removal rate of a material to be polished, and paragraph “0043” of the Publication lists “polypropylene glycol (PPG), polyethylene glycol (PEG)” as suitable examples of the polishing speed inhibitor. It was surprising that the polishing removal rate of a carbon film was enhanced by allowing a specified water-soluble polymer to be contained in a polishing composition as in the present invention. Thus, it was entirely unexpected that the polishing removal rate of a carbon film would be markedly increased by incorporating a specific water-soluble polymer, -one that would ordinarily be expected to protect the substrate and therefore lower the polishing removal rate-into the polishing composition of the present invention.

The highest occupied molecular orbital (HOMO) energy level of the water-soluble polymer can be affected by, for example, the presence or absence of electron-donating ability of a functional group in the water-soluble polymer, the electron density, the presence or absence of structural branching, the presence or absence of an atom having a lone pair of electrons, the number of such atoms, and/or the like. For example, when, for example, a hydroxy group is present in the structure of the water-soluble polymer, the hydroxy group has an electron-donating effect and can raise the HOMO energy level. Therefore, according to one embodiment of the present invention, the water-soluble polymer may have 1 to 5 hydroxy groups, 2 to 4 hydroxy groups, or 2 or 3 hydroxy groups. According to one embodiment of the present invention, the water-soluble polymer has two hydroxy groups. When, for example, an oxyalkylene group is contained in the structure of the water-soluble polymer, an oxygen atom present in the oxyalkylene group has a lone pair of electrons and therefore this pair of electrons can increase the HOMO energy. Therefore, according to one embodiment of the present invention, the water-soluble polymer has an oxyalkylene group. According to one embodiment of the present invention, the number of carbon atoms in the oxyalkylene group of the water-soluble polymer can be 1 to 4. Examples of the oxyalkylene group include an oxyethylene group or an oxypropylene group. Examples of the water-soluble polymer having an oxyethylene group include polyethylene glycol. Examples of the water-soluble polymer having an oxypropylene group include polypropylene glycol. When the structure of polypropylene glycol and the structure of polyethylene glycol are compared, polypropylene glycol has a methyl group not contained in polyethylene glycol and the methyl group can function as an electron-donating group, and thus the HOMO energy tends to increase in the case of comparison by the same molecular weight (for example, comparison between Examples 6 and 8, and Examples 9 and 11).

The HOMO energy of the water-soluble polymer can be affected by the presence or absence of electron-donating ability, the electron density, the presence or absence of structural branching, the presence or absence of an atom having a lone pair of electrons, and the number of such atoms, as described above, and therefore this (these) can be appropriately selected and controlled so that a water-soluble polymer having a highest occupied molecular orbital (HOMO) energy level of −10.00 eV or more can be prepared.

The HOMO level adopted herein is a value calculated with a PM7 method (Parametric Method 7) corresponding to the Hamiltonian of semi-empirical molecular orbital method program MOPAC.

In a case where the highest occupied molecular orbital (HOMO) energy level of the water-soluble polymer is less than −10.00 eV, the polishing removal rate of an object to be polished (for example, carbon film) may deteriorate. The highest occupied molecular orbital (HOMO) energy level of the water-soluble polymer can be, for example, −9.9 eV or more, −9.8 eV or more, −9.7 eV or more, −9.6 e V or more, −9.5 eV or more, −9.4 eV or more, −9.3 eV or more, −9.2 eV or more, −9.0 eV or more, −8.5 eV or more, −8.0 eV or more, or −7.5 eV or more. The upper limit of the highest occupied molecular orbital (HOMO) energy level of the water-soluble polymer can be, for example, −7.5 eV or less, −8.0 eV or less, −8.5 eV or less, −9.0 eV or less, −9.4 eV or less, or −9.8 eV or less.

According to one embodiment of the present invention, the water-soluble polymer having a highest occupied molecular orbital (HOMO) energy level of −10.00 eV or more is a polyalkylene glycol having a weight average molecular weight (molecular weight) of 100 to 1500. The polyalkylene glycol here also encompasses, for example, an oligomer having 3 repeating units, like 3,6-dioxa-1,8-octanediol. According to one embodiment of the present invention, the average number of repeating units in the water-soluble polymer having a highest occupied molecular orbital (HOMO) energy level of −10.00 eV or more can be, for example, 2 to 50, 5 to 40, or 10 to 30.

According to one embodiment of the present invention, the water-soluble polymer having a highest occupied molecular orbital (HOMO) energy level of −10.00 eV or more is polyethylene glycol having a weight average molecular weight (molecular weight) of 100 or more and 1500 or less, more than 200 and less than 1000, or more than 400 and less than 1000.

According to one embodiment of the present invention, the water-soluble polymer having a highest occupied molecular orbital (HOMO) energy level of −10.00 eV or more is polypropylene glycol having a weight average molecular weight (molecular weight) of 100 or more and 1500 or less, 200 or more and less than 1000, or 300 or more and less than 700.

The content (concentration) of the water-soluble polymer having a highest occupied molecular orbital (HOMO) energy level of −10.00 eV or more in the polishing composition is not particularly limited, and can be more than 100 ppm by mass, 150 ppm by mass or more, 200 ppm by mass or more, 250 ppm by mass or more, 300 ppm by mass or more, 350 ppm by mass or more, 400 ppm by mass or more, more than 400 ppm by mass, 450 ppm by mass or more, 500 ppm by mass or more, 550 ppm by mass or more, 600 ppm by mass or more, 650 ppm by mass or more, 700 ppm by mass or more, 750 ppm by mass or more, 800 ppm by mass or more, more than 800 ppm by mass, 1100 ppm by mass or more, 1400 ppm by mass or more, 1700 ppm by mass or more, 2000 ppm by mass or more, more than 2000 ppm by mass, 2100 ppm by mass or more, 2200 ppm by mass or more, 2300 ppm by mass or more, 2400 ppm by mass or more, 2800 ppm by mass or more, 3000 ppm by mass or more, more than 3000 ppm by mass, 3200 ppm by mass or more, or 3400 ppm by mass or more. The content (concentration) of the water-soluble polymer having a highest occupied molecular orbital (HOMO) energy level of −10.00 eV or more in the polishing composition is not particularly limited, and can be, for example, 5000 ppm by mass or less, 4500 ppm by mass or less, 4000 ppm by mass or less, less than 4000 ppm by mass, 3500 ppm by mass or less, 3000 ppm by mass or less, less than 3000 ppm by mass, 2700 ppm by mass or less, 2400 ppm by mass or less, 2100 ppm by mass or less, 2000 ppm by mass or less, less than 2000 ppm by mass, 1600 ppm by mass or less, 1300 ppm by mass or less, 900 ppm by mass or less, 800 ppm by mass or less, less than 800 ppm by mass, or 600 ppm by mass or less. According to one embodiment of the present invention, the content (concentration) of the water-soluble polymer having a highest occupied molecular orbital (HOMO) energy level of −10.00 eV or more in the polishing composition is more than 100 ppm by mass and 5000 ppm by mass or less. Such a range allows the effect of an enhancement in the polishing removal rate of the carbon film to be more remarkable.

The content (concentration) of the water-soluble polymer having a highest occupied molecular orbital (HOMO) energy level of −10.00 eV or more in the polishing composition is preferably more than 400 ppm by mass and less than 4000 ppm by mass, more preferably more than 400 ppm by mass and less than 3000 ppm by mass, further preferably more than 400 ppm by mass and less than 2000 ppm by mass. Such a range allows the effect of an enhancement in the polishing removal rate of the carbon film to be more remarkable.

The polishing composition according to the present invention may contain a water-soluble polymer other than the water-soluble polymer having a highest occupied molecular orbital (HOMO) energy level of −10.00 eV or more. Here, the proportion of the water-soluble polymer having a highest occupied molecular orbital (HOMO) energy level of −10.00 eV or more in the water-soluble polymer is 80% by mass or more, 85% by mass or more, 90% by mass or more, 95% by mass or more, 98% by mass or more, or 99% by mass or more (upper limit 100% by mass) from the viewpoint of allowing the intended effects of the present invention to be efficiently exerted.

### [Liquid Carrier]

The polishing composition according to the present invention contains a liquid carrier. The liquid carrier has the function of dispersing or dissolving a component contained in the polishing composition. According to a more preferred embodiment of the present invention, the liquid carrier is substantially composed of water. The “substantially” means that a liquid carrier other than water can be contained as long as the effects of the present invention are achieved. More specifically, the liquid carrier is preferably composed of 90% by mass or more and 100% by mass or less of water and 0% by mass or more and 10% by mass or less of the liquid carrier other than water, more preferably composed of 99% by mass or more and 100% by mass or less of water and 0% by mass or more and 1% by mass or less of the liquid carrier other than water. Most preferably, the liquid carrier is constituted from only water.

Examples of the liquid carrier other than water can include alcohols such as methanol, ethanol, and ethylene glycol; ketones such as acetone, and any mixture of these.

The water preferably does not contain impurities as much as possible from the viewpoint of not inhibiting the action of a component contained in the polishing composition. Specifically, more preferred is pure water or ultrapure water obtained by removing impurity ions with an ion exchange resin and then removing foreign substances through a filter, or distilled water.

### [pH and pH Adjusting Agent]

The pH of the polishing composition according to the present invention can be 8.0 or less, 7.0 or less, less than 7.0, 6.0 or less, 5.5 or less, 5.0 or less, less than 5.0, 4.0 or less, 3.0 or less, less than 3.0, 2.9 or less, 2.8 or less, 2.7 or less, 2.6 or less, 2.5 or less, 2.4 or less, or 2.3 or less. In particular, when the pH is less than 5.0 or less than 3.0, the polishing removal rate of the object to be polished including the carbon film is remarkably enhanced. The lower limit of the pH can be 1.0 or more, 1.1 or more, 1.2 or more, 1.3 or more, 1.4 or more, 1.5 or more, 1.6 or more, 1.7 or more, 1.8 or more, 1.9 or more, 2.0 or more, or 2.1 or more. In other words, the pH of the polishing composition according to the present invention can be, 1.0 or more and 8.0 or less, 1.1 or more and 7.0 or less, 1.2 or more and less than 7.0, 1.3 or more and 6.0 or less, 1.4 or more and 5.5 or less, 1.5 or more and less than 5.0, 1.6 or more and 4.0 or less, 1.7 or more and 3.0 or less, 1.8 or more and less than 3.0, 1.9 or more and 2.9 or less, 2.0 or more and 2.8 or less, 2.0 or more and 2.7 or less, 2.0 or more and 2.6 or less, 2.0 or more and 2.5 or less, 2.0 or more and 2.4 or less, or 2.1 or more and 2.3 or less.

The polishing composition according to the present invention contains a pH adjusting agent for adjusting the pH. The pH adjusting agent may be any one or more of an inorganic acid, an organic acid, and a base, and may be any one or more of an inorganic compound and an organic compound. The pH adjusting agent can be used singly or as a mixture of two or more kinds thereof.

Specific examples of the inorganic acid usable as the pH adjusting agent include hydrochloric acid, sulfuric acid, nitric acid, hydrofluoric acid, boric acid, carbonic acid, hypophosphorous acid, phosphorus acid, and phosphonic acid, and phosphoric acid. In particular, preferred is hydrochloric acid, sulfuric acid, nitric acid or phosphoric acid or the combination thereof.

Specific examples of the organic acid usable as the pH adjusting agent include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid and phenoxyacetic acid. Organic sulfuric acids such as methanesulfonic acid, ethanesulfonic acid and isethionic acid may also be used. In particular, preferred are dicarboxylic acids such as malonic acid, succinic acid, glutaric acid, adipic acid, pimelic acid, maleic acid, phthalic acid, malic acid and tartaric acid, and tricarboxylic acids such as citric acid.

A salt of the inorganic acid or the organic acid, such as an alkali metal salt, may be used as the pH adjusting agent, instead of the inorganic acid or the organic acid, or in combination with the inorganic acid or the organic acid. In the case of a combination of a weak acid and a strong base, a strong acid and a weak base, or a weak acid and a weak base, a pH-buffering action can be expected. Specific examples of the base usable as the pH adjusting agent can include ammonia, sodium hydroxide, potassium hydroxide, and tetramethylammonium hydroxide. The amount of addition of the pH adjusting agent is not particularly limited, and may be appropriately adjusted so that the polishing composition has a desired pH.

The pH of the polishing composition can be measured with, for example, a pH meter, and specifically can be measured by the method described in Examples.

### [Other Components]

The polishing composition according to the present invention may or may not further contain known additive(s) for use in polishing compositions, such as an oxidizing agent, a complexing agent, an antiseptic agent, and/or an antifungal agent, as long as the effects of the present invention are not impaired. In particular, an oxidizing agent is preferably contained.

The oxidizing agent has the effect of oxidizing a surface of the object to be polished, and can more enhance the polishing removal rate of the object to be polished by the polishing composition.

Examples of the oxidizing agent include hydrogen peroxide, sodium peroxide, barium peroxide, ozone water, a silver (II) salt, an iron (III) salt, permanganic acid, chromatic acid, bichromatic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, dichloroisocyanuric acid and salts thereof (for example, a potassium salt, a sodium salt, and an ammonium salt). These oxidizing agents can be used singly or in combinations of two or more kinds thereof. In particular, hydrogen peroxide, ammonium persulfate, periodic acid, hypochlorous acid, and sodium dichloroisocyanurate are preferred, and hydrogen peroxide is more preferred.

The lower limit of the content of the oxidizing agent in the polishing composition is preferably 0.001% by mass or more, preferably 0.01% by mass or more. When the lower limit is such a value, the polishing removal rate can be more enhanced. The upper limit of the content of the oxidizing agent in the polishing composition is preferably 30% by mass or less, more preferably 10% by mass or less. When the upper limit is such a value, not only the material cost of the polishing composition can be suppressed, but also treatment of the polishing composition after use for polishing, namely, the load of waste water treatment can be lessened. In addition, the risk of excess oxidation occurring on a surface of an object to be polished due to the oxidizing agent can also be decreased.

According to one embodiment of the present invention, the antifungal agent (antiseptic agent) is not particularly limited, and can be appropriately selected depending on desired application and object. Specific examples include 1,2-benzisothiazol-3 (2H)-one (BIT), isothiazoline-based antiseptic agents such as 2-methyl-4-isothiazolin-3-one and 5-chloro-2-methyl-4-isothiazolin-3-one, and phenoxyethanol.

According to one embodiment of the present invention, the polishing composition does not contain a nitrogen-containing organic compound other than antifungal agent (antiseptic agent); if any such compound is present, its concentration may be less than 10 mM. When the polishing composition does not contain a nitrogen-containing organic compound, steric hindrance to the object to be polished due to the presence of the nitrogen-containing organic compound can be significantly suppressed and the effect of an enhancement in polishing removal rate can be expected.

According to one embodiment of the present invention, the polishing composition does not contain an anionic surfactant, or even if it does, the anionic surfactant is at less than 50 ppm by mass in the polishing composition. When the polishing composition does not contain an anionic surfactant, an adsorption of the anionic surfactant onto the cation-modified abrasive is prevented, so charge reduction is minimized and the effect of an enhancement in polishing removal rate can be expected. In the embodiment, the anionic surfactant is one having an anionic group in its structure, and examples of the anionic group include one or more functional groups selected from the group consisting of a sulfuric acid group, a sulfonic acid group and a phosphoric acid group.

According to one embodiment of the present invention, the polishing composition does not contain a trialkylamine oxide, or even if it does, the trialkylamine oxide is present at less than 3 ppm by mass in the polishing composition. When the amount of such a trialkylamine oxide is kept to a minimum, a suitable charge can be maintained on the organic film, thereby enhancing its polishing removal rate.

The polishing composition disclosed in the present invention can allow a carbon film to be polished at a high polishing removal rate. Therefore, a polishing composition used for the polishing of a carbon film is provided.

### [Method for Producing Polishing Composition]

The method for producing the polishing composition according to the present invention is not particularly limited, and can be obtained by, for example, stirring and mixing a cation-modified abrasive, a specified water-soluble polymer, a pH adjusting agent, and, if necessary, any other additive in water. The detail of each component is as described above. The temperature in mixing of each component is not particularly limited, and is preferably 10° C. or more and 40° C. or less, and heating may be performed in order to increase the rate of dissolution. The mixing time is also not particularly limited as long as uniform mixing can be achieved.

### [Polishing Method and Method for Producing Semiconductor Substrate]

As described above, the polishing composition according to the present invention is suitably used in the polishing of an object to be polished having a carbon film. Accordingly, the present invention provides a polishing method for polishing an object to be polished having a carbon film, with the polishing composition according to the present invention. The present invention also provides a method for producing a semiconductor substrate, the method including polishing a semiconductor substrate having a carbon film, by the polishing method.

The polishing apparatus used here can be a common polishing apparatus in which a holder for retaining a substrate or the like having an object to be polished and a motor or the like changeable in number of rotations are installed and which has a polishing table (platen) to which a polishing pad (polishing cloth) can be pasted. The polishing pad used here can be common non-woven cloth, polyurethane, porous fluororesin, and the like without any particular limitation. The polishing pad is preferably grooved so that a polishing liquid is accumulated. Among polishing conditions, for example, the rotational speed of the polishing table is preferably 10 rpm (0.17 s⁻¹) or more and 500 rpm (8.33 s⁻¹) or less. The pressure (polishing pressure) to be applied to a substrate having an object to be polished is preferably 0.5 psi (3.4 kPa) or more and 10 psi (68.9 kPa) or less. The method for supplying the polishing composition to the polishing pad is also not particularly limited, and, for example, a continuous-supplying method with a pump or the like is adopted. While the amount of supply is not limited, a surface of the polishing pad is preferably always covered with the polishing composition according to the present invention. After completion of polishing, the substrate is washed in flowing water and dried by blowing off water droplets attached onto the substrate with a spin drier or the like, and thus a substrate having a layer including a carbon film is obtained.

The polishing composition according to the present invention may be of a one-liquid type or a multi-liquid type, for example, a two-liquid type. The polishing composition according to the present invention may also be prepared by diluting a liquid concentrate of the polishing composition with a dilution liquid such as water, for example, 10-fold or more.

The present invention includes the following aspects and modes.
1. A polishing composition comprising a cation-modified abrasive having an average secondary particle diameter of 80 nm or more, a water-soluble polymer or a polyalkylene glycol (preferably having a weight average molecular weight (molecular weight) of 100 to 1500) having a highest occupied molecular orbital (HOMO) energy level of −10.00 eV or more, and a liquid carrier.
2. The polishing composition according to 1., wherein the polishing composition has a pH of less than 7.
3. The polishing composition according to 2., wherein the polishing composition has a pH of less than 3.
4. The polishing composition according to any one of 1. to 3., wherein a concentration of the water-soluble polymer is more than 100 ppm by mass and 5000 ppm by mass or less.
5. The polishing composition according to any one of 1. to 4., wherein the water-soluble polymer has two hydroxy groups.
6. The polishing composition according to any one of 1. to 5., wherein the water-soluble polymer has an oxyalkylene group.
7. The polishing composition according to any one of 1. to 6., wherein the average secondary particle diameter is 140 nm or more.
8. The polishing composition according to any one of 1. to 7., wherein the number of silanol groups in the cation-modified abrasive is 6/nm² or more and 22/nm² or less.
9. The polishing composition according to any one of 1. to 8., wherein the composition is used for polishing a carbon film.

### EXAMPLES

The present invention is described in further detail with reference to the following Examples and Comparative Examples. However, the technical scope of the present invention is not limited to only the following Examples. Unless particularly noted, “%” and “part(s)” respectively mean “% by mass” and “part(s) by mass”.

### [Preparation of Polishing Composition]

### Example 1

A water dispersion of colloidal silica (concentration of silica particle: 23.5% by mass, average primary particle diameter: 90 nm, average secondary particle diameter: 210 nm) as a silica raw material was prepared. While the water dispersion of colloidal silica, prepared as above, was stirred with a stirring blade at a stirring rate of 250 rpm, γ-aminopropyltriethoxysilane (hereinafter, also referred to as “APTES”) was directly dropped without dilution. The amount of addition of APTES was set so as to be 0.12% by mass based on 100% by mass of the silica particle included in the silica raw material. Thereafter, the reaction system was kept in the state of being stirred at ordinary temperature (25° C.) for 5 hours without heating, thereby obtaining cation-modified (amino group-modified) colloidal silica where an amino group was introduced to a silica particle surface.

Thereafter, pure water as a liquid carrier, PEG600 as a water-soluble polymer, nitric acid as a pH adjusting agent, and the cation-modified abrasive were mixed, and stirred and mixed at room temperature (25° C.) for 30 minutes, thereby preparing a polishing composition of Example 1 so as to allow the concentration of the cation-modified abrasive, the concentration of the water-soluble polymer, and the value of the pH to be as shown in Table 1.

### Examples 2 to 14 and Comparative Examples 1 to 6

A polishing composition of each Example or each Comparative Example was prepared by changing the cation-modified abrasive (cation-modified colloidal silica), changing the water-soluble polymer, and changing the pH, as shown in Table 1. In the Table, the designation “-” indicates no addition of the relevant component. The silica raw materials used for preparing the cation-modified abrasives in Example 13 and Comparative Examples 2 and 3 were respectively colloidal silica (concentration of silica particle: 20% by mass, average primary particle diameter: 90 nm, average secondary particle diameter: 120 nm), colloidal silica (concentration of silica particle: 20% by mass, average primary particle diameter: 27 nm, average secondary particle diameter: 50 nm), and colloidal silica (concentration of silica particle: 20% by mass, average primary particle diameter: 41 nm, average secondary particle diameter: 70 nm). According to this, the zeta potential and the silanol group density were also different from those for the cation-modified abrasive in Example 1. The cation-modified abrasive used in Example 14 was one having a different silanol group density from that of the cation-modified abrasive in Example 1.

The zeta potential of the raw material silica fell in the range from 30 to 50 mV in all Examples-Comparative Examples. The pH of the water dispersion of the raw material silica fell in the range from 7.3 to 7.5 in all Examples-Comparative Examples. The zeta potential of the raw material silica was measured in the same manner as in the zeta potential of the cation-modified abrasive in the polishing composition described below. The pH of the water dispersion of the raw material silica was measured in the same manner as in the pH of the polishing composition described below.

### [Various Kinds of Measurement]

### <Particle Diameter>

The values of the average secondary particle diameter (particle diameter) of the colloidal silica particle of the silica raw material and the average secondary particle diameter of the cation-modified abrasive in the polishing composition, adopted here, were values measured as the volume average particle diameters by a dynamic light scattering method with a particle diameter distribution measurement apparatus (UPA-UT151, manufactured by Nikkiso Co., Ltd.). The values of the average primary particle diameter of the colloidal silica particle of the silica raw material and the average primary particle diameter of the cation-modified abrasive in the polishing composition were calculated by the expression of primary particle diameter=6000/(SA×2.2) with 2.2 g/cm³ as the true specific gravity of silica, based on the specific surface area (SA) of the silica particle, as calculated from a BET method. It was here confirmed that the average secondary particle diameter and the average primary particle diameter were not particularly changed before and after modification.

### <Measurement of Zeta Potential>

Measurement of the zeta potential of the cation-modified abrasive was performed with a zeta potential measurement apparatus (trade name “ELS-Z”) manufactured by Otsuka Electronics Co., Ltd. The results are shown in Table 1.

### <Method for Calculating Number of Silanol Groups>

The number of silanol groups (unit:/nm²) per unit surface area of the cation-modified abrasive was calculated by the following method after measurement or calculation of each parameter, by the following measurement method or calculation method.

More specifically, C in the following expression is the total mass of the cation-modified abrasive, and S in the following expression is the BET specific surface area of the cation-modified abrasive. Further specifically, first, 1.50 g of the cation-modified abrasive as a solid content is collected in a 200-ml beaker, 100 ml of pure water is added to provide a slurry, and then 30 g of sodium chloride is added and dissolved. Next, 1 N hydrochloric acid is added to adjust the pH of the slurry to 3.0 to 3.5, and then pure water is added until 150 ml of the slurry is obtained.

An automatic titration apparatus (COM-1700 manufactured by Hiranuma Co., Ltd.) is used in the slurry to adjust the pH to 4.0 with 0.1 N sodium hydroxide at 25° C., and furthermore measure the volume V [L] of the 0.1 N sodium hydroxide solution necessary for an increase in pH from 4.0 to 9.0 by pH titration. The average silanol group density (number of silanol groups) can be calculated by the following expression.

$$p = ( c \times V \times {N}_{A} ) / ( C \times S )$$

wherein
ρ represents the average silanol group density (number of silanol groups) (/nm²);
c represents the concentration (mol/L) of the sodium hydroxide solution used for titration;
V represents the volume (L) of the sodium hydroxide solution necessary for an increase in pH from 4.0 to 9.0;
N_{A} represents the Avogadro constant (molecules/mol);
C represents the total mass (solid content) (g) of the cation-modified abrasive; and
S represents the weighted average value (nm²/g) of the BET specific surface area of the cation-modified abrasive. The BET specific surface area is the value of the specific surface area of the cation-modified abrasive by a BET method, as measured with “MacsorbHM model-1210” manufactured by Mountech Co., Ltd. The results are shown in Table 1.

### <Calculation of Highest Occupied Molecular Orbital (HOMO) Energy>

The highest occupied molecular orbital (HOMO) energy (highest occupied molecular orbital (HOMO) energy level) of the water-soluble polymer was determined with quantum chemical calculation software MOPAC, and structure optimization was performed by an EF method. Molecular orbital energy calculation was performed with the structure obtained by the structure optimization, according to a semi-empirical molecular orbital method PM7. The results are shown in Table 1.

### <Measurement of pH of Polishing Composition>

The pH of the polishing composition was measured with a pH meter (Model number: F-71, manufactured by Horiba Ltd.). The results are shown in Table 1.

### <Polishing Removal Rate>

A silicon wafer (300-mm wafer manufactured by Advanced Materials Technology, Inc.) where a film of amorphous carbon was formed at a thickness of 2000 Å on a surface was prepared. The wafer prepared was polished with the polishing composition obtained above, under the following polishing conditions, and the polishing removal rate was measured:

### (Polishing Conditions)

Polishing machine: EJ-380 IN-CH (manufactured by Engis Japan Corporation)
Polishing pad: hard polyurethane pad (IC1010 manufactured by Rohm and Haas)
Polishing pressure: 1.4 psi (1 psi=6894.76 Pa)
Number of rotations of platen (table): 40 rpm
Number of rotations of head (carrier): 40 rpm
Flow rate of polishing composition: 16 ml/min
Polishing time: 6 seconds.

The polishing removal rate was calculated by the following expression

$$Polishing removal rate [ Å / min ] = ( Film thickness [ Å ] before polishing - Film thickness [ Å ] after polishing ) / Polishing time ( min ) \qquad [ Expression 1 ]$$

The film thickness was determined with an ellipsometric film thickness measurement apparatus (Model number: RE3500, manufactured by SCREEN Holdings Co., Ltd.), and the difference in film thickness before and after polishing was divided by the polishing time, thereby calculating the polishing removal rate. The results are shown in Table 1. The polishing removal rate is preferably 450 Å/min or more, 500 Å/min or more, 550 Å/min or more, or 600 Å/min or more at a polishing pressure of 1.4 psi. The upper limit of the polishing removal rate is, for example, 650 Å/min.

TABLE 1

| | | | | | | Water-soluble polymer/ | | | | |
|---|---|---|---|---|---|---|---|---|---|---|
| | Cation-modified colloidal silica | | | | | Water-soluble compound | | | | |
| | | | | Silanol | | | | Amount of | pH of | Polishing |
| | | Particle | Z | group | pH | | | addition | polishing | removal |
| | Concentration | diameter | potential | density | adjusting | | HOMO | [ppm by | composition | rate |
| | % by mass | nm | mV | [/nm²] | agent | Type | [eV] | mass] | [—] | [Å/min] |
| Example 1 | 0.1 | 210 | 49 | 7.9 | Nitric acid | PEG600 | −9.471 | 800 | 2.2 | 611 |
| Example 2 | 0.1 | 210 | 49 | 7.9 | Nitric acid | PEG600 | −9.471 | 400 | 2.2 | 511 |
| Example 3 | 0.1 | 210 | 49 | 7.9 | Nitric acid | PEG600 | −9.471 | 2000 | 2.2 | 580 |
| Example 4 | 0.1 | 210 | 49 | 7.9 | Nitric acid | PEG600 | −9.471 | 3000 | 2.2 | 523 |
| Example 5 | 0.1 | 210 | 49 | 7.9 | Nitric acid | PEG600 | −9.471 | 4000 | 2.2 | 477 |
| Example 6 | 0.1 | 210 | 49 | 7.9 | Nitric acid | PEG400 | −9.497 | 800 | 2.2 | 609 |
| Example 7 | 0.1 | 210 | 49 | 7.9 | Nitric acid | PEG200 | −9.525 | 800 | 2.2 | 553 |
| Example 8 | 0.1 | 210 | 49 | 7.9 | Nitric acid | PPG400 | −9.169 | 800 | 2.2 | 637 |
| Example 9 | 0.1 | 210 | 49 | 7.9 | Nitric acid | PEG1000 | −9.171 | 800 | 2.2 | 587 |
| Example 10 | 0.1 | 210 | 49 | 7.9 | Nitric acid | PPG700 | −9.199 | 800 | 2.2 | 628 |
| Example 11 | 0.1 | 210 | 49 | 7.9 | Nitric acid | PPG1000 | −7.847 | 800 | 2.2 | 570 |
| Example 12 | 0.1 | 210 | 49 | 7.9 | Nitric acid | 3,6-Dioxa-1,8- | −9.873 | 800 | 2.2 | 517 |
| | | | | | | octanediol | | | | |
| Example 13 | 0.1 | 120 | ≈40 | 6.6 | Nitric acid | PEG600 | −9.471 | 800 | 3.0 | 600 |
| Example 14 | 0.1 | 210 | 49 | 2.5 | Nitric acid | PEG600 | −9.471 | 800 | 2.2 | 463 |
| Comparative | 0.1 | 210 | 49 | 7.9 | Nitric acid | — | — | — | 2.2 | 50 |
| Example 1 | | | | | | | | | | |
| Comparative | 0.1 | 50 | 30 | 3.7 | Nitric acid | PEG600 | −9.471 | 800 | 2.2 | 386 |
| Example 2 | | | | | | | | | | |
| Comparative | 0.1 | 70 | ≈35 | 5.5 | Nitric acid | PEG600 | −9.471 | 800 | 2.2 | 412 |
| Example 3 | | | | | | | | | | |
| Comparative | 0.1 | 210 | 49 | 7.9 | Nitric acid | Ethylene | −10.624 | 800 | 2.2 | 58 |
| Example 4 | | | | | | glycol | | | | |
| Comparative | 0.1 | 210 | 49 | 7.9 | Nitric acid | Diethylene | −10.152 | 800 | 2.2 | 67 |
| Example 5 | | | | | | glycol | | | | |
| Comparative | 0.1 | 210 | 49 | 7.9 | Nitric acid | PVA | * | 100 | 2.2 | 37 |
| Example 6 | | | | | | Mw10000 | | | | |

* HOMO could not be calculated due to too high molecular weight of water-soluble polymer
PEG200: Polyethylene glycol having weight average molecular weight of 200
PEG400: Polyethylene glycol having weight average molecular weight of 400
PEG600: Polyethylene glycol having weight average molecular weight of 600
PEG1000: Polyethylene glycol having weight average molecular weight of 1000
PPG400: Polypropylene glycol having weight average molecular weight of 400
PPG700: Polypropylene glycol having weight average molecular weight of 700
PPG1000: Polypropylene glycol having weight average molecular weight of 700
PVA: Polyvinyl alcohol having weight average molecular weight of 10000

The present application is based on Japanese Patent Application No. 2025-056938 filed on Mar. 28, 2025, the disclosure of which is herein incorporated by reference in its entirety.

1. A polishing composition comprising:
a cation-modified abrasive having an average secondary particle diameter of 80 nm or more;
a water-soluble polymer having a highest occupied molecular orbital (HOMO) energy level of −10.00 eV or more; and
a liquid carrier.

2. The polishing composition according to claim 1, wherein the polishing composition has a pH of less than 7.

3. The polishing composition according to claim 2, wherein the polishing composition has a pH of less than 3.

4. The polishing composition according to claim 1, wherein a concentration of the water-soluble polymer is more than 100 ppm by mass and 5000 ppm by mass or less.

5. The polishing composition according to claim 1, wherein the water-soluble polymer has two hydroxy groups.

6. The polishing composition according to claim 1, wherein the water-soluble polymer has an oxyalkylene group.

7. The polishing composition according to claim 1, wherein the average secondary particle diameter is 140 nm or more.

8. The polishing composition according to claim 1, wherein the number of silanol groups in the cation-modified abrasive is 6/nm² or more and 22/nm² or less.

9. The polishing composition according to claim 1, wherein the composition is used for polishing a carbon film.
